(19) United States
(12) Patent Application Publication
(10) Pub. No.: US 2026/0075863 A1
(43) Pub. Date: Mar. 12, 2026

(54) SEMICONDUCTOR DEVICE AND FORMING METHOD OF THE SAME

(71) Applicant: Ancora Semiconductors Inc., Taoyuan City (TW)

(72) Inventors: Li-Fan LIN, Taoyuan City (TW); Ying-Chen LIU, Taoyuan City (TW)

(21) Appl. No.: 18/830,558

(22) Filed: Sep. 10, 2024

(51) Int. Cl. H01L 29/417; H01L 29/40; H01L 29/45; H01L 29/47

(52) U.S. Cl. CPC H10D 30/475; H10D 30/6738; H10D 30/675; H10D 62/85; H10D 64/112; H10D 64/62; H10D 64/64; H10W 20/484

(57) ABSTRACT

A semiconductor device includes an active layer having an active region, a source electrode, a drain electrode, and a gate electrode disposed on the active region of the active layer and extending along a first direction, and multiple first P-GaN islands disposed on the active region and under the drain electrode. A vertical projection of the drain electrode on the active region covers the entirety of a vertical projection of each of the first P-GaN islands on the active region.

### BACKGROUND

### Field of Disclosure

The present disclosure relates to a semiconductor device and a forming method of the semiconductor device.

### Description of Related Art

A power semiconductor device is used as a switch under high pressure. The on-state resistance gradually becomes larger after being used more times. Thus, there is a need to provide a semiconductor device that may solve the problem mentioned above.

### SUMMARY

A semiconductor device includes an active layer having an active region, a source electrode, a drain electrode, and a gate electrode disposed on the active region of the active layer and extending along a first direction, and multiple first P-GaN islands disposed on the active region and under the drain electrode. A vertical projection of the drain electrode on the active region covers the entirety of a vertical projection of each of the first P-GaN islands on the active region.

A semiconductor device includes an active layer having an active region, a source electrode, a drain electrode, and a gate electrode disposed on the active region of the active layer and extending along a first direction, and multiple ohmic metal layers. The gate electrode includes a gate P-GaN layer and a metal layer. The ohmic metal layers are disposed between the gate P-GaN layer and the metal layer. The material of the ohmic metal layers is the same as the drain electrode and the source electrode.

A forming method of a semiconductor device includes forming a gate P-GaN layer, a plurality of first P-GaN islands, and a plurality of second P-GaN islands on the active layer simultaneously, and the gate P-GaN layer extends along a first direction. The forming method further includes forming a drain electrode, a source electrode, and a plurality of ohmic metal layers simultaneously. The source electrode is disposed on the active layer, the drain electrode covers the gate P-GaN layer, and the ohmic metal layers are disposed on the gate P-GaN layer. The forming method further includes forming multiple field plates disposed on the P-GaN islands.

In the aforementioned embodiments, the first P-GaN islands are used as hole injection layers to absorb the trapped charges in the drain electrode. The second P-GaN islands are used as hole injection layers to absorb the trapped charges in the field plates. The ohmic metal layers are used as hole injection layers to absorb the trapped charges in the gate electrode. Therefore, the semiconductor device of the present disclosure can reduce on-state resistance by disposing first P-GaN islands under the drain electrode, by disposing the second P-GaN islands under the field plates, and by disposing ohmic metal laeyrs between the gate P-GaN layer and the metal layer of the gate electrode.

### BRIEF DESCRIPTION OF THE DRAWINGS

FIG. 1 is a top view of a semiconductor device according to one embodiment of the present disclosure.

FIG. 2A is a cross-sectional view along line 2A-2A of FIG. 1.

FIG. 2B is a cross-sectional view of a semiconductor device accordingly to another embodiment of the present disclosure.

FIG. 3A is a top view of the semiconductor device omitting the second source metal layer, the second drain metal layer, the source pad, and the drain pad.

FIG. 3B is a top view of the semiconductor device in FIG. 2B omitting the second source metal layer, the second drain metal layer, the source pad, and the drain pad.

FIG. 4A is a top view of a semiconductor device according to another embodiment of the present disclosure.

FIG. 4B is a top view of a semiconductor device according to another embodiment of the present disclosure. FIG. 5A is a cross-sectional view along line 5A-5A of FIG. 4A.

FIG. 5B is a cross-sectional view along line 5B-5B of FIG. 4B.

FIG. 6 is a cross-sectional view of an intermediate stage of a forming method of a semiconductor device according to one embodiment of the present disclosure.

FIG. 7 is a top view of FIG. 6.

FIG. 8 is a cross-sectional view of an intermediate stage of a forming method of a semiconductor device according to one embodiment of the present disclosure.

FIG. 9 is a top view of FIG. 8.

FIG. 10 is a cross-sectional view of an intermediate stage of a forming method of a semiconductor device according to one embodiment of the present disclosure.

FIG. 11 is a top view of FIG. 10.

FIG. 12 is a cross-sectional view of an intermediate stage of a forming method of a semiconductor device according to one embodiment of the present disclosure.

FIG. 13 is a top view of FIG. 12.

FIG. 14 is a cross-sectional view of an intermediate stage of a forming method of a semiconductor device according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

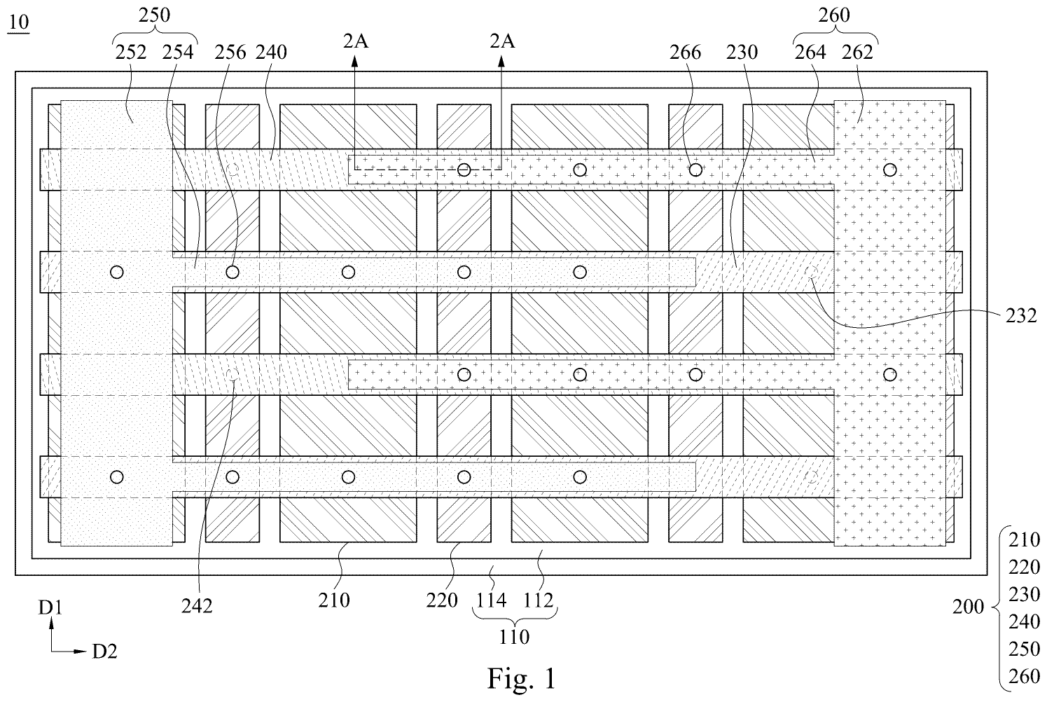

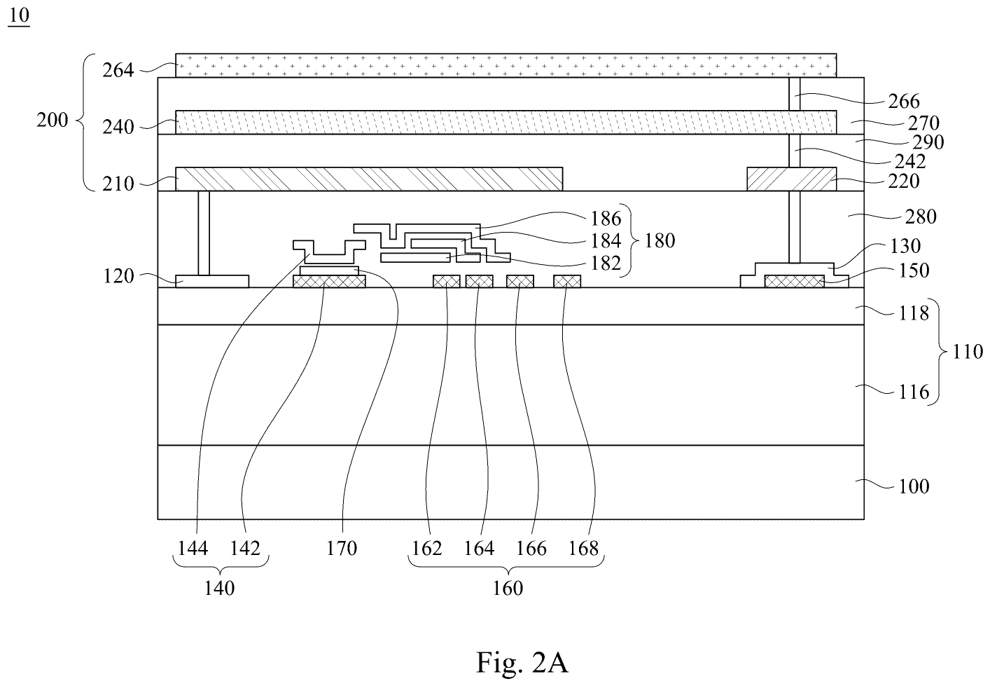

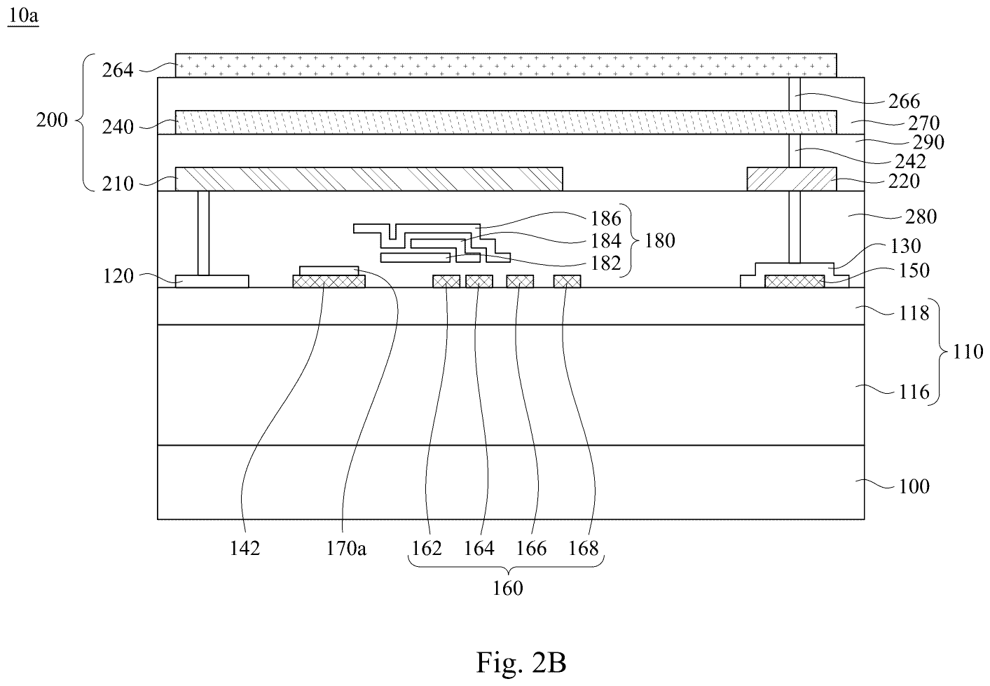

FIG. 1 is a top view of a semiconductor device 10 according to some embodiments of the present disclosure. FIG. 2A is a cross-sectional view along line 2A-2A of FIG. 1. Reference is made to FIG. 1 and FIG. 2A. The semiconductor device 10 includes an active layer 110, a source electrode 120, a drain electrode 130, a gate electrode 140, multiple first P-GaN islands 150, multiple second P-GaN islands 160, multiple ohmic metal islands 170, and multiple field plates 180.

Reference is made to FIG. 1 and FIG. 2A. The active layer 110 includes a channel layer 116 and a barrier layer 118 disposed on the channel layer 116. The active layer 110 has an active region 112. In some embodiments, the channel layer 116 can be made of GaN, and the barrier layer 118 can be made of AlGaN. The active layer 110 further includes an insulating region 114 surrounding the active region 112. The insulating region 114 may be formed by implanting ions, such as oxygen, nitrogen, carbon, or the like, into the active layer 110. In some other embodiments, the insulating region 114 is a shallow trench isolation (STI). The active layer 110 may be selectively disposed on a substrate 100.

Reference is made to FIG. 1 and FIG. 2A. The source electrodes 120, the drain electrodes 130, the gate electrodes 140 are disposed on the active region 112 of the active layer 110 and extend along a first direction D1. The semiconductor device 10 further includes multiple metal layers 200. The metal layers includes a first source metal layer 210 disposed on and the source electrode 120 and the gate electrode 140, a first drain metal layer 220 disposed on the drain electrode 130, a second source metal layer 230 disposed on the first source metal layer 210 and the first drain metal layer 220, a second drain metal layer 240 disposed on the first source metal layer 210 and the first drain metal layer 220, a source pad 250, and a drain pad 260.

The first source metal layer 210 is electrically connected to the source electrode 120. The first drain metal layer 220 is electrically connected to the drain electrode 130. The second source metal layer 230 is electrically connected to the first source metal layer 210. The second drain metal layer 240 is electrically connected to the first drain metal layer 220. The source pad 250 is electrically connected to the second source metal layer 230, and the drain pad 260 is electrically connected to the second drain metal layer 240.

In the present embodiment, the first source metal layer 210 and the first drain metal layer 220 extend along the first direction D1. The second source metal layer 230 and the second drain metal layer 240 extend along the second direction D2. The source pad 250 includes a body portion 252 extending along the first direction D1 and multiple branch portions 254 extending along the second direction D2. The drain pad 260 includes a body portion 262 extending along the first direction D1 and multiple branch portions 264 extending along the second direction D2.

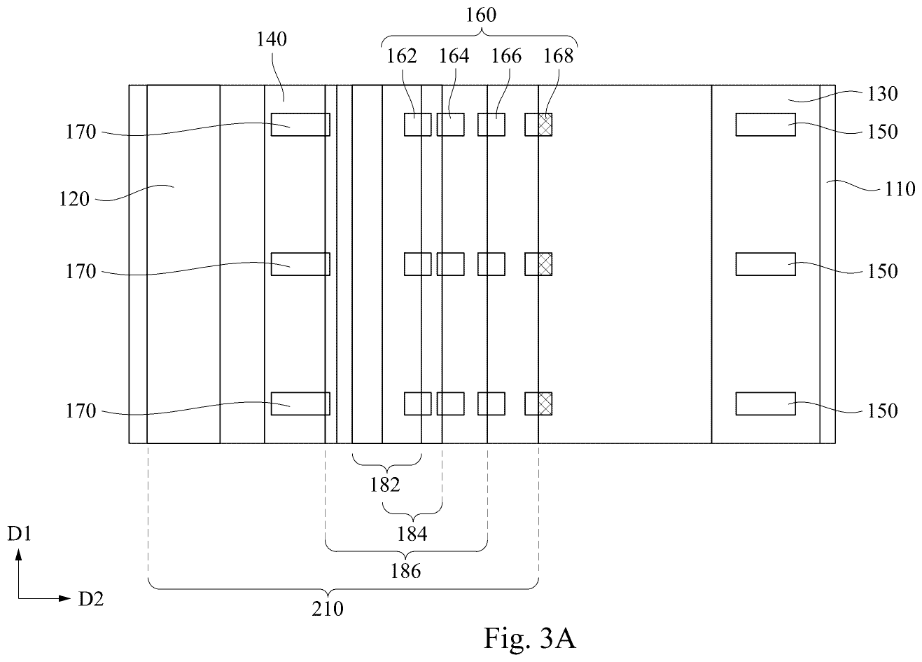

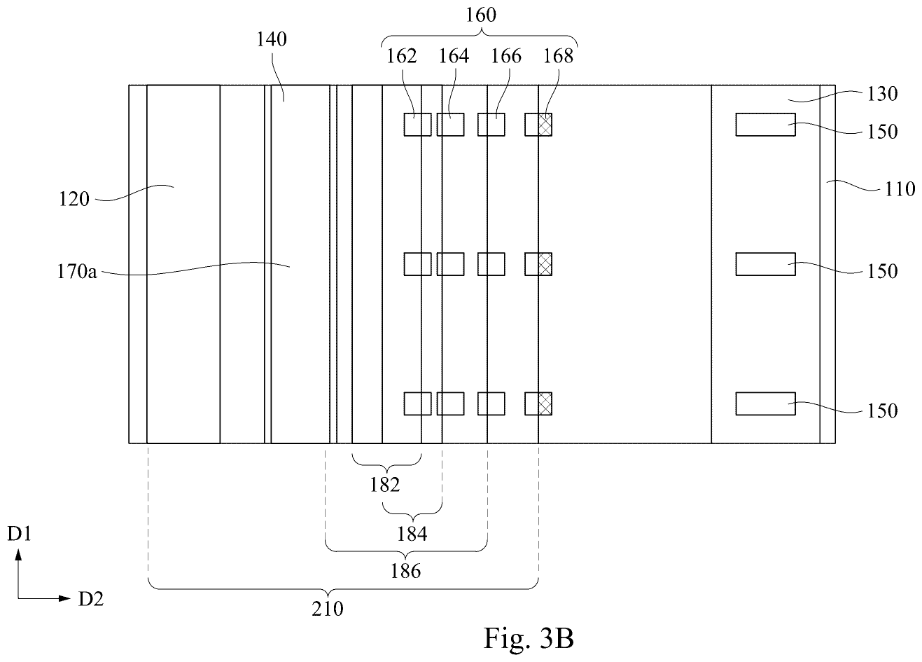

FIG. 3A is a top view of the semiconductor device 10 omitting the second source metal layer, the second drain metal layer, the source pad, and the drain pad. Reference is made to FIG. 2A and FIG. 3A. The first P-GaN islands 150 are disposed on the active region 112 and under the drain electrode 130. The source electrode 120 and the drain electrode 130 extend along the first direction D1. The first P-GaN islands 150 are arranged along the first direction D1, and a sidewall of each of the first P-GaN islands 150 are surrounded by the drain electrode 130. A vertical projection of the drain electrode 130 on the active region 112 covers the entirety of a vertical projection of each of the first P-GaN islands 150 on the active region 112.

Charges are trapped in the regions under and surrounding the drain electrode 130 and at the interface between the first P-GaN islands 150 and the barrier layer 118 after usage, and therefore the on-state resistance of the semiconductor device 10 becomes larger. The first P-GaN islands 150 are used as hole injection layers to neutralize the trapped charges in the regions described above. Therefore, the on-state resistance can be reduced by disposing the first P-GaN islands 150 between the active layer 110 and the drain electrode 130.

Reference is made to FIG. 2A and FIG. 3A. Multiple field plates 180 are disposed between the source electrode 120 and the drain electrode 130 and on the active region 112. The field plates 180 extend along the first direction D1. The second P-GaN islands 160 disposed one the active region 112 and under the field plates 180. The second P-GaN islands 160 are arranged along the first direction D1 and the second direction D2.

Reference is made to FIG. 2A and FIG. 3A. The field plates 180 includes a first field plate 182 disposed level with the schottky metal layer 144 of the gate electrode 140, a second field plate 184 covering the first field plate 182, and a third field plate 186 covering the first field plate 182, the second field plate 184.

Reference is made to FIG. 2A and FIG. 3A. The second P-GaN islands 160 include a first column 162, a second column 164, a third column 166, and a fourth column 168. The first column 162 is located between the gate electrode 140 and the second column 164. The first column 162 overlaps an edge of the first field plate 182 in the plan view. The second column 164 is located between the first column 162 and the third column 166. The second column 164 overlaps an edge of the second field plate 184. The third column 166 is located between the second column 164 and the fourth column 168. The third column 166 overlaps an edge of the third field plate 186. The fourth column 168 is located between the third column 166 and the first P-GaN islands 150. The fourth column 168 overlaps an edge of the first source metal layer 210.

The second P-GaN islands 160 are used as hole injection layers to neutralize the trapped charges in the regions under and surrounding the field plates 180. Therefore, the on-state resistance can be reduced by disposing the second P-GaN islands 160 between the active layer 110 and the field plates 180.

The gate electrode 140 includes a gate P-GaN layer 142 and a schottky metal layer 144 above the gate P-GaN layer 142. The gate P-GaN layer 142 and the schottky metal layer 144 both extend along the first direction D1. The ohmic metal islands 170 are disposed between the gate P-GaN layer 142 and the schottky metal layer 144, and are arranged along the first direction D1. The material of the ohmic metal islands is the same as the drain electrode 130 and the source electrode 120.

The ohmic metal islands 170 are used as hole injection layers to absorb the trapped charges in the regions under and surrounding the gate electrode 140. Therefore, the on-state resistance can be reduced by disposing the ohmic metal islands 170 between the gate P-GaN layer 142 and the schottky metal layer 144 of the gate electrode 140.

The semiconductor device 10 further includes a dielectric layer 270. The dielectric layer 270 covers the second source metal layers 230 and the second drain metal layers 240. The source pad 250 and the drain pad 260 are disposed on the dielectric layer 270. The source pad 250 is electrically connected to the second source metal layers 230 through vias 256 disposed in the dielectric layer 270. The drain pad 260 is electrically connected to the second drain metal layers 240 through vias 266 disposed in the dielectric layer 270.

The semiconductor device 10 further includes dielectric layers 280 and 290. For clarity, the dielectric layers 280 and 290 are merely illustrated in FIG. 2A. The dielectric layer 280 is disposed on the active layer 110. The dielectric layer 280 covers the source electrode 120, the drain electrode 130, and the gate electrodes 140. The first source metal layers 210 are disposed on the dielectric layer 280 and cover the source electrode 120 and/or the gate electrodes 140, and the first drain metal layers 220 are disposed on the dielectric layer 280 and cover the drain electrode 130.

The dielectric layer 290 covers the first source metal layers 210 and the first drain metal layers 220. In other words, the first source metal layers 210 and the first drain metal layers 220 are disposed between the dielectric layers 290 and 280, and the second source metal layers 230 and the second drain metal layers 240 are disposed between the dielectric layers 290 and 270.

The second source metal layers 230 are disposed on the dielectric layer 290 and are electrically connected to the first source metal layers 210 through vias 232 disposed in the dielectric layer 290. The second drain metal layers 240 are disposed on the dielectric layer 290 and are electrically connected to the first drain metal layers 220 through vias 242 disposed in the dielectric layer 290.

FIG. 2B is a cross-sectional view of a semiconductor device 10a accordingly to another embodiment of the present disclosure. FIG. 3B is a top view of the semiconductor device 10a in FIG. 2B omitting the second source metal layer, the second drain metal layer, the source pad, and the drain pad. In the present embodiment, an ohmic metal layer 170a is disposed on a gate P-GaN layer. The ohmic metal layer extends along the first direction D1. There is no schottky metal layer 144.

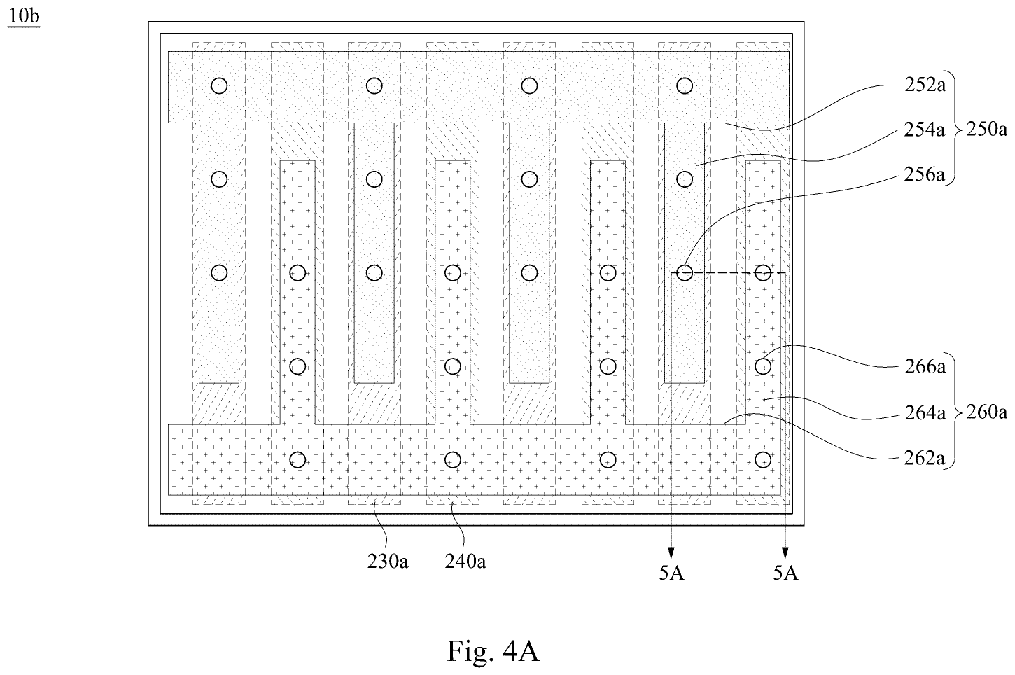

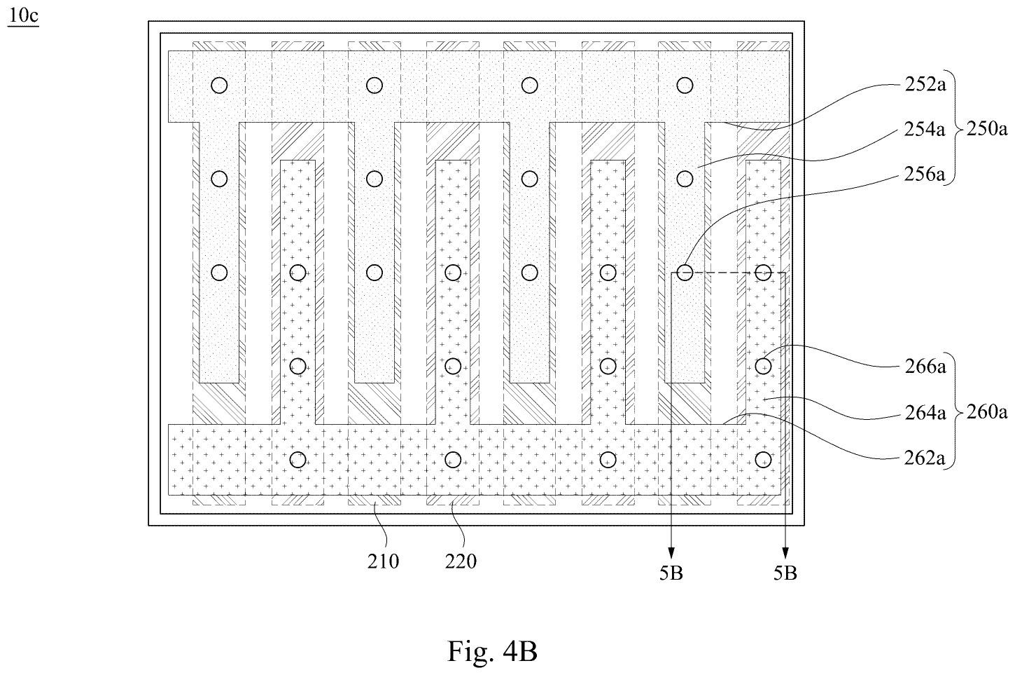

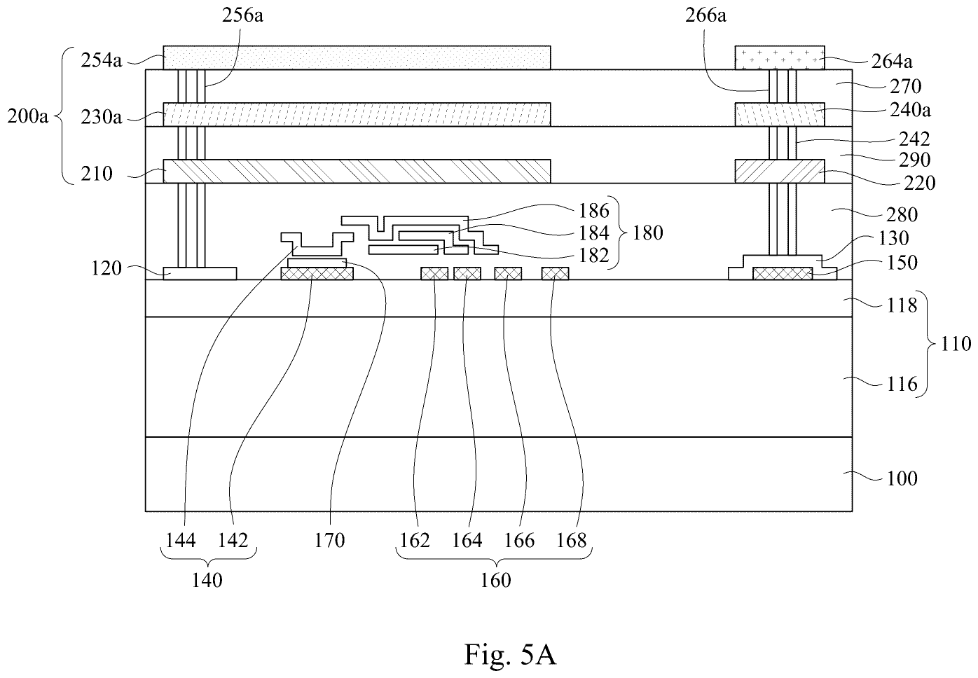

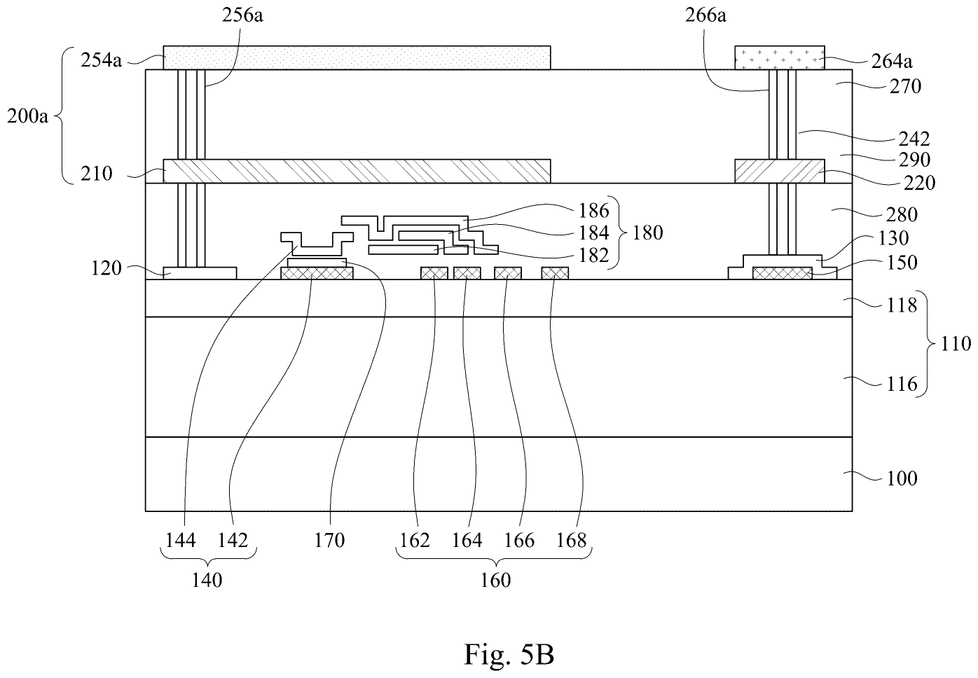

FIG. 4A is a top view of a semiconductor device 10b according to another embodiment of the present disclosure. FIG. 5A is a cross-sectional view along line 5A-5A of FIG. 4A. Reference is made to FIG. 4A and FIG. 5A. The semiconductor device 10a is similar to the semiconductor device 10 in FIG. 1 to FIG. 3A, and the difference is the configuration of the metal layers 200a. The first source metal layers 210a, the first drain metal layers 220a, the second source metal layers 230a, and the second drain metal layers 240a extend along the first direction D1. The body portion 252a of the source pad 250a and the body portion 262a of the drain pad 260a extend along the second direction D2. The branch portions 254a of the source pad 250a and the branch portions 264a of the drain pad 260a extend along the first direction D1. The semiconductor device 10a and the semiconductor device 10 have the same advantages, and therefore the description is not repeated hereafter.

FIG. 4B is a top view of a semiconductor device according 10c to another embodiment of the present disclosure. FIG. 5B is a cross-sectional view along line 5B-5B of FIG. 4B. The semiconductor device 10c is similar to the semiconductor device 10b, and the difference is that the semiconductor device 10c has no second source metal layer 230a and the second drain metal layer 240a shown in FIG. 4A and FIG. 5A.

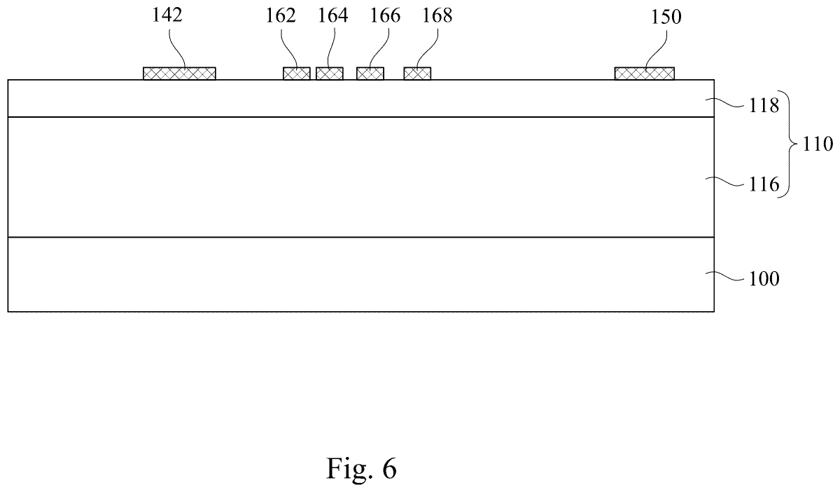

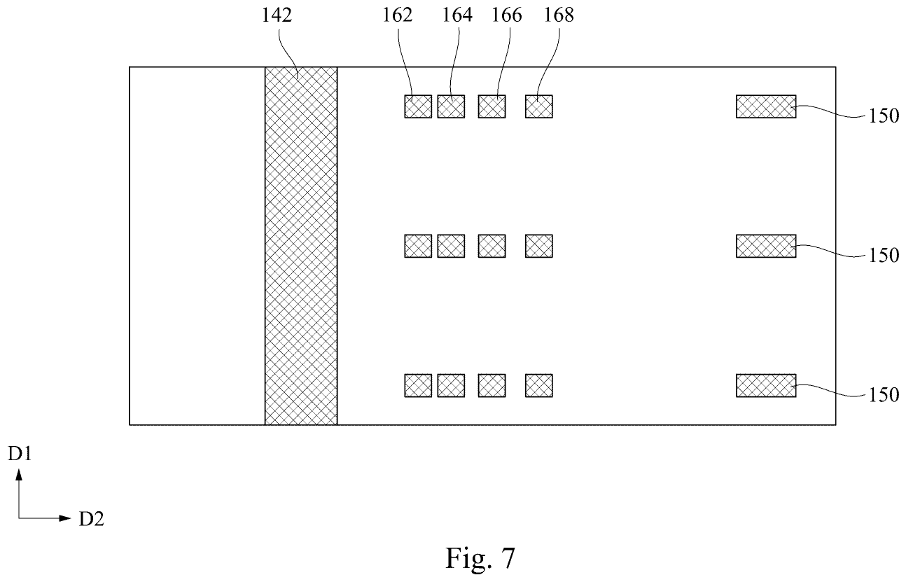

FIG. 6 is a cross-sectional view of an intermediate stage of a forming method of a semiconductor device according to one embodiment of the present disclosure. FIG. 7 is a top view of FIG. 6. Reference is made to FIG. 6 and FIG. 7. The forming method of the semiconductor device begins with forming the gate P-GaN layer 142, the first P-GaN islands 150, and the second P-GaN islands 160 on the active layer 110 simultaneously. Specifically, this step is defining all the P-GaN layers through patterning. As such, the gate P-GaN layer 142 is defined to extend along the first direction D1. The first P-GaN islands 150 are defined to be arranged along the first direction D1. The second P-GaN islands 160 are defined to be arranged along the first direction D1 and the second direction D2.

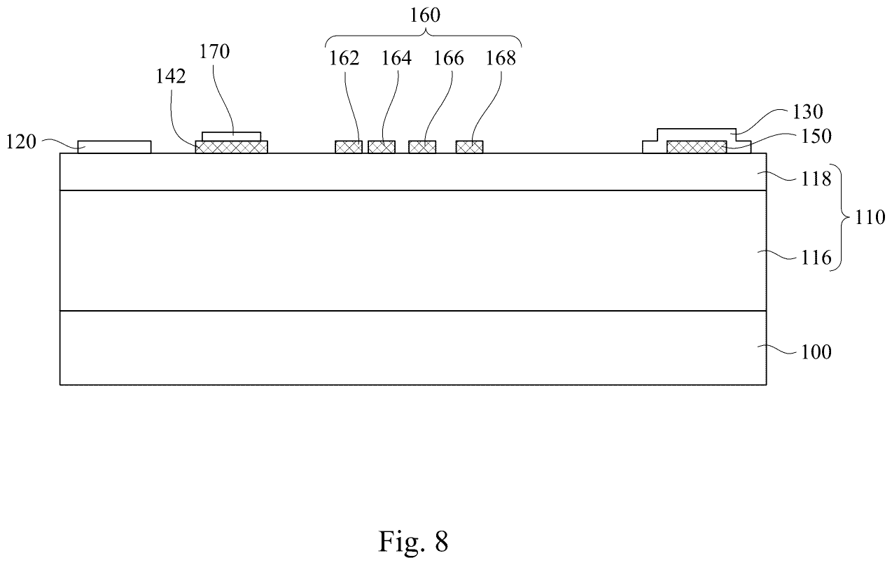

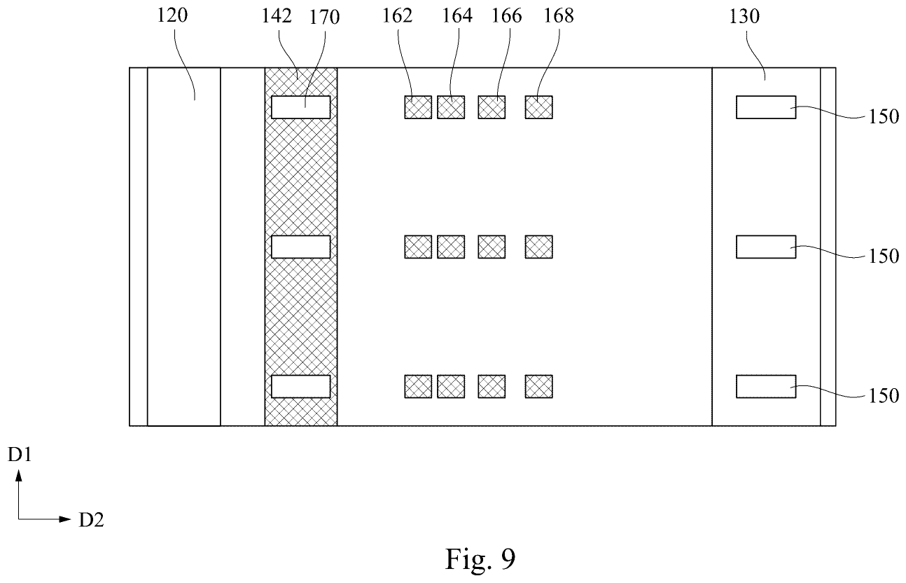

FIG. 8 is a cross-sectional view of an intermediate stage of a forming method of a semiconductor device according to one embodiment of the present disclosure. FIG. 9 is a top view of FIG. 8. Reference is made to FIG. 8 and FIG. 9. The forming method continues with forming the drain electrode 130, the source electrode 120, and multiple ohmic metal islands 170 simultaneously. Specifically, this step is defining all the layers whose material is ohmic metal through patterning.

The drain electrode 130 is defined to extend along the first direction and covers the first P-GaN islands 150. The ohmic metal islands 170 is defined to be disposed on the gate P-GaN layer 142 and be arranged along the first direction D1. After forming the drain electrode 130, the source electrode 120, and the ohmic metal islands 170, annealing process is performed thereon. The ohmic metal islands 170 becomes semi-ohmic regions that can be used as hole injection layers.

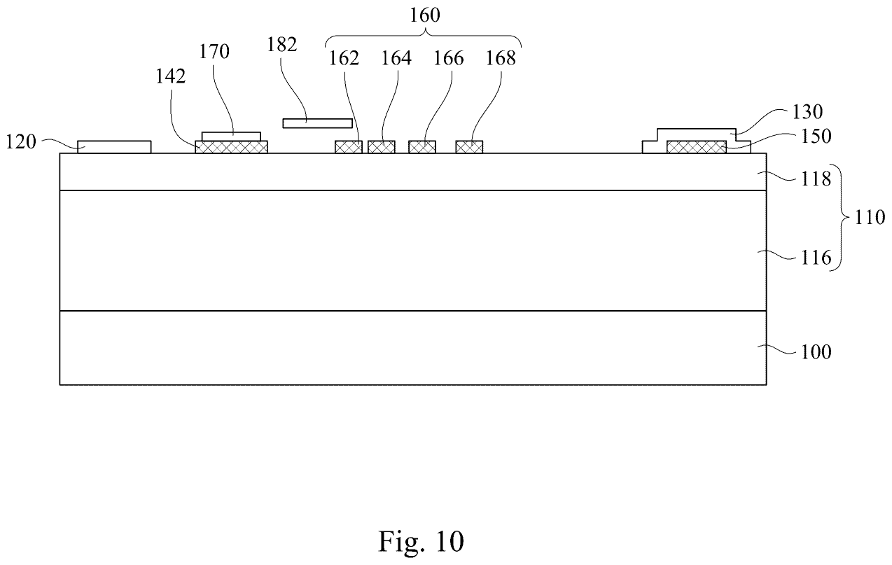

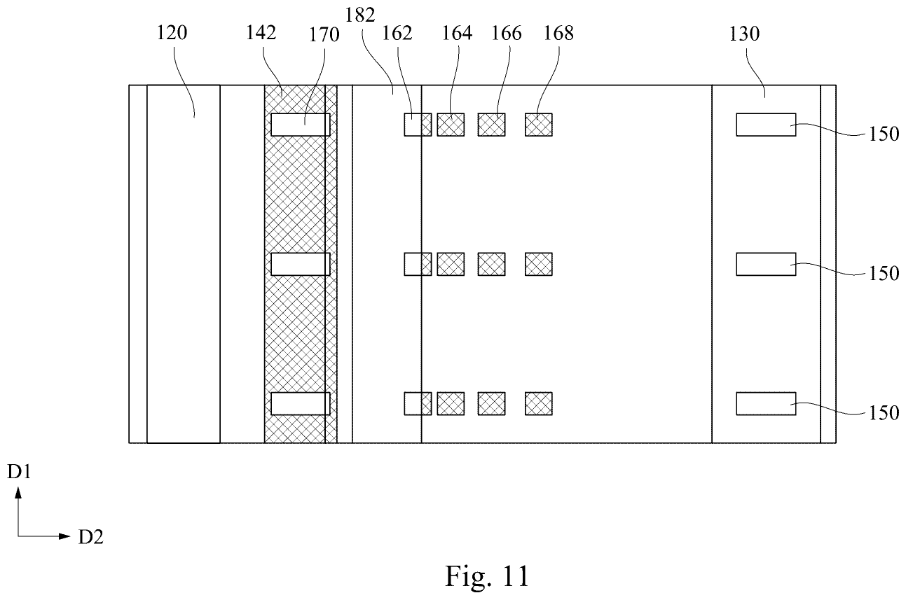

FIG. 10 is a cross-sectional view of an intermediate stage of a forming method of a semiconductor device according to one embodiment of the present disclosure. FIG. 11 is a top view of FIG. 10. Reference is made to FIG. 10 and FIG. 11. The forming method continues with forming the first field plate 182 such that an edge of the first field plate 182 overlaps the first column 162 of the second P-GaN islands 160.

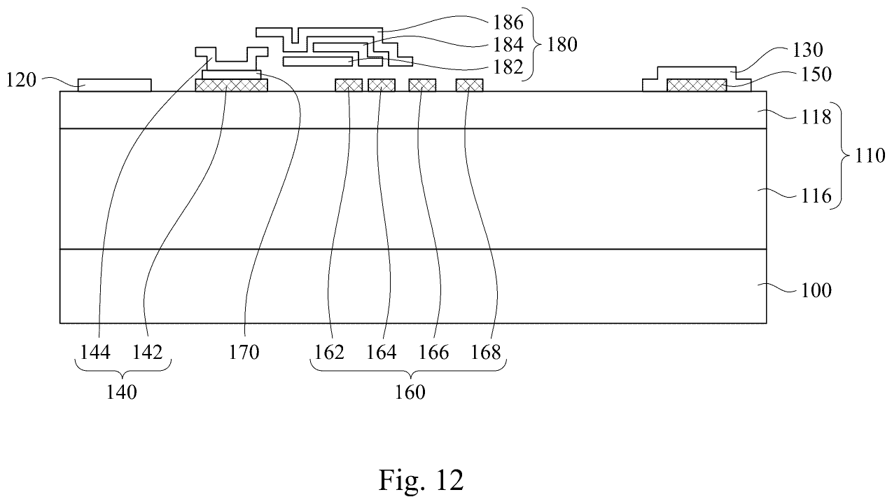

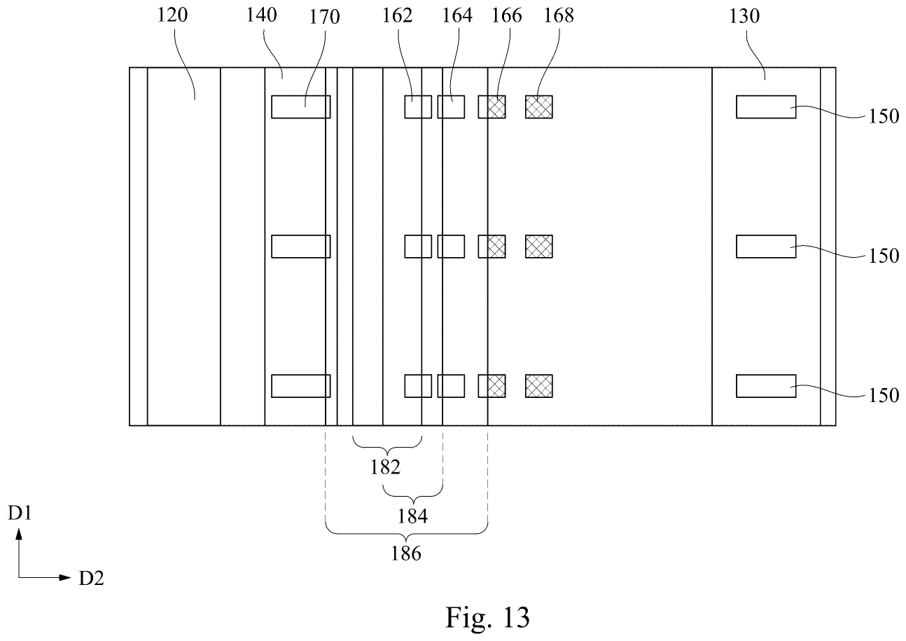

FIG. 12 is a cross-sectional view of an intermediate stage of a forming method of a semiconductor device according to one embodiment of the present disclosure. FIG. 13 is a top view of FIG. 12. Reference is made to FIG. 12 and FIG. 13. The forming method continues with forming the second field plate 184 and the schottky metal layer 144. The schottky metal layer 144 extends along the first direction D1 and covers the gate P-GaN layer 142 and the ohmic metal islands 170. An edge of the second field plate 184 overlaps the second column 164 of the second P-GaN islands 160.

The forming method further continues with forming the third field plate 186 such that an edge of the third field plate 186 overlaps the third column 166 of the second P-GaN islands 160.

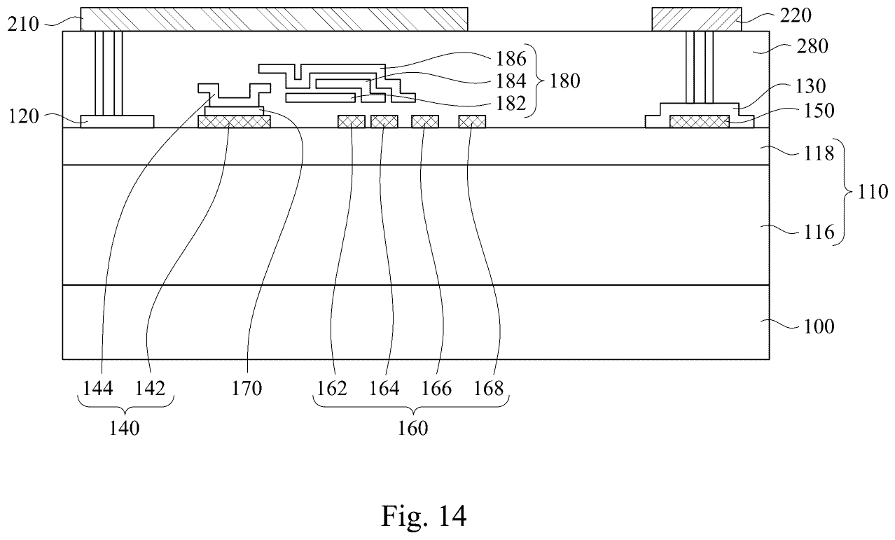

FIG. 14 is a cross-sectional view of an intermediate stage of a forming method of a semiconductor device according to one embodiment of the present disclosure. The forming method continues with forming the first source metal layer 210 and the first drain metal layer 220 such that an edge of the first source metal layer 210 overlaps the fourth column 168 of the second P-GaN islands 160.

In summary, the first P-GaN islands are used as hole injection layers to absorb the trapped charges in the in the regions under and surrounding the drain electrode and at the interface between the first P-GaN islands and the underlying layer. The second P-GaN islands are used as hole injection layers to absorb the trapped charges in the in the regions under and surrounding field plates. The ohmic metal layers are used as hole injection layers to absorb the trapped charges in the in the regions under and surrounding gate electrode. Therefore, the semiconductor device of the present disclosure can reduce on-state resistance by disposing first P-GaN islands under the drain electrode, by disposing the second P-GaN islands under the field plates, and by disposing ohmic metal laeyrs between the gate P-GaN layer and the metal layer of the gate electrode.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. A semiconductor device, comprising:
an active layer having an active region;
a source electrode, a drain electrode, and a gate electrode disposed on the active region of the active layer and extending along a first direction;
a plurality of first P-GaN islands disposed on the active region and under the drain electrode, wherein a vertical projection of the drain electrode on the active region covers the entirety of a vertical projection of each of the first P-GaN islands on the active region.

2. The semiconductor device of claim 1, wherein the first P-GaN islands are arranged along the first direction, and a sidewall of each of the first P-GaN islands are surrounded by the drain electrode.

3. The semiconductor device of claim 1, further comprising:
a plurality of field plates disposed between the source electrode and the drain electrode, wherein the field plates extend along the first direction; and
a plurality of second P-GaN islands disposed one the active region and under the field plates.

4. The semiconductor device of claim 3, wherein the second P-GaN islands are arranged along the first direction and a second direction.

5. The semiconductor device of claim 1, wherein the gate electrode comprises a gate P-GaN layer and a schottky metal layer, and the semiconductor device further comprises:
a plurality of ohmic metal islands disposed between the gate P-GaN layer and the schottky metal layer.

6. The semiconductor device of claim 5, wherein the ohmic metal islands are arranged along the first direction.

7. The semiconductor device of claim 5, wherein the material of the ohmic metal islands is the same as the drain electrode and the source electrode.

8. The semiconductor device of claim 1, wherein the gate electrode comprises a gate P-GaN layer and an ohmic metal layer disposed on the gate P-GaN layer.

9. The semiconductor device of claim 1, further comprising:
a first source metal layer disposed on the source electrode and the gate electrode, wherein the first source metal layer is electrically connected to the source electrode and extend along the first direction; and
a first drain metal layer disposed on the drain electrode, wherein the first drain metal layer is electrically connected to the drain electrode and extend along the first direction.

10. The semiconductor device of claim 9, further comprising:
a second source metal layer disposed on the first source metal layer and the first drain metal layer, wherein the second source metal layer is electrically connected to the first source metal layer and extends along a second direction;
a second drain metal layer disposed on the first source metal layer and the first drain metal layer, wherein the second drain metal layer is electrically connected to the first drain metal layer and extends along the second direction;
a source pad disposed on the second source metal layer and the second drain metal layer, wherein the source pad is electrically connected to the second source metal layer; and
a drain pad disposed on the second source metal layer and the second drain metal layer, wherein the drain pad is electrically connected to the second drain metal layer.

11. The semiconductor device of claim 9, further comprising:
a second source metal layer disposed on the first source metal layer and the first drain metal layer, wherein the second source metal layer is electrically connected to the first source metal layer and extends along the first direction;
a second drain metal layer disposed on the first source metal layer and the first drain metal layer, wherein the second drain metal layer is electrically connected to the first drain metal layer and extends along the first direction;
a source pad disposed on the second source metal layer and the second drain metal layer, wherein the source pad is electrically connected to the second source metal layer; and
a drain pad disposed on the second source metal layer and the second drain metal layer, wherein the drain pad is electrically connected to the second drain metal layer.

12. The semiconductor device of claim 9, further comprising:
a source pad disposed on the first source metal layer and the first drain metal layer, wherein the source pad is electrically connected to the first source metal layer; and
a drain pad disposed on the first source metal layer and the first drain metal layer, wherein the drain pad is electrically connected to the first drain metal layer.

13. A semiconductor device, comprising:
an active layer having an active region;
a source electrode, a drain electrode, and a gate electrode disposed on the active region of the active layer and extending along a first direction, wherein the gate electrode comprises a gate P-GaN layer and a schottky metal layer; and
a plurality of ohmic metal islands disposed between the gate P-GaN layer and the schottky metal layer, wherein the material of the ohmic metal islands is the same as the drain electrode and the source electrode.

14. The semiconductor device of claim 13, wherein the ohmic metal islands are arranged along the first direction.

15. The semiconductor device of claim 13, further comprising:
a plurality of first P-GaN islands disposed one the active region and under the drain electrode, wherein a vertical projection of the drain electrode on the active region covers the entirety of a vertical projection of each of the first P-GaN islands on the active region, the first P-GaN islands are arranged along the first direction, and a sidewall of each of the first P-GaN islands are surrounded by the drain electrode.

16. The semiconductor device of claim 13, further comprising:
a plurality of field plates disposed between the source electrode and the drain electrode, wherein the field plates extend along the first direction; and
a plurality of second P-GaN islands disposed one the active region and under the field plates, wherein the second P-GaN islands are arranged along the first direction and a second direction.

17. A forming method of a semiconductor device, comprising:
forming a gate P-GaN layer of a gate electrode, a plurality of first P-GaN islands, and a plurality of second P-GaN islands on an active layer simultaneously, wherein the gate P-GaN layer extends along a first direction;
forming a drain electrode, a source electrode, and a plurality of ohmic metal islands simultaneously, wherein the source electrode is disposed on the active layer, the drain electrode covers the first P-GaN islands, and the ohmic metal islands are disposed on the gate P-GaN layer; and
forming a plurality of field plates disposed on the second P-GaN islands.

18. The forming method of the semiconductor device of claim 17, further comprising:
after forming the ohmic metal islands, annealing the ohmic metal islands.

19. The forming method of the semiconductor device of claim 17, wherein the source electrode and the drain electrode extend along the first direction, and the plurality of ohmic metal islands are arranged along the first direction.

20. The forming method of the semiconductor device of claim 17, wherein the plurality of first P-GaN islands are arranged along the first direction, and the plurality of second P-GaN islands are arranged along the first direction and a second direction.

21. The forming method of the semiconductor device of claim 17, further comprising:
forming a first source metal layer disposed on the source electrode and the gate electrode, wherein the first source metal layer is electrically connected to the source electrode and extend along the first direction; and
forming a first drain metal layer disposed on the drain electrode, wherein the first drain metal layer is electrically connected to the drain electrode and extend along the first direction.

22. The forming method of the semiconductor device of claim 21, further comprising:
forming a second source metal layer disposed on the first source metal layer and the first drain metal layer, wherein the second source metal layer is electrically connected to the first source metal layer;
forming a second drain metal layer disposed on the first source metal layer and the first drain metal layer, wherein the second drain metal layer is electrically connected to the first drain metal layer;
forming a source pad disposed on the second source metal layer and the second drain metal layer, wherein the source pad is electrically connected to the second source metal layer; and
forming a drain pad disposed on the second source metal layer and the second drain metal layer, wherein the drain pad is electrically connected to the second drain metal layer.
